(19) United States
(12) Patent Application Publication
(10) Pub. No.: US 2026/0025132 A1
(43) Pub. Date: Jan. 22, 2026

(54) SWITCH CONTROL CIRCUIT AND METHOD FOR CONTROLLING SWITCHES THEREOF, AND RADIO FREQUENCY SWITCH

(71) Applicant: Samsung Electro-Mechanics Co., Ltd., Suwon-si (KR)

(72) Inventors: Wonsun HWANG, Suwon-si (KR); Byeonghak JO, Suwon-si (KR); Shinhaeng HEO, Suwon-si (KR)

(73) Assignee: Samsung Electro-Mechanics Co., Ltd., Suwon-si (KR)

(21) Appl. No.: 18/895,781

(22) Filed: Sep. 25, 2024

(30) Foreign Application Priority Data
Jul. 17, 2024 (KR) 10-2024-0094650

(51) Int. Cl. H03K 17/16; H03K 5/13; H03K 19/20

(52) U.S. Cl. CPC H03K 17/16; H03K 5/13; H03K 19/20

(57) ABSTRACT

A switch control circuit of an RF switch circuit is provided. The switch control circuit includes a decoder configured to output first and second command signals; a first driver configured to generate a first switching control signal having a turn-on voltage or turn-off voltage in response to the first command signal, and output the first switching control signal to a first switch; a delay cell configured to delay the second command signal; a logic gate configured to generate a third command signal through a logical operation performed on the second command signal and the delayed second command signal; and a second driver configured to generate a second switching control signal having a turn-on voltage or a turn-off voltage in response to the third command signal, and output the second switching control signal to a second switch connected between the first port and ground or between the second port and ground.

### CROSS-REFERENCE TO RELATED APPLICATIONS

This application claims the benefit under 35 USC § 119(a) of Korean Patent Application No. 10-2024-0094650 filed on Jul. 17, 2024, in the Korean Intellectual Property Office, the entire disclosure of which is incorporated herein by reference for all purposes.

### BACKGROUND

### 1. Field

This following description relates to a switch control circuit, a switch control method thereof, and a radio frequency switch circuit.

### 2. Description of Related Art

In a wireless communication system, a front-end module (FEM) may include a power amplifier, a low noise amplifier, and a radio frequency (RF) switch circuit.

The frequency at which the FEM operates may be divided into frequency division duplex (FDD) and time division duplex (TDD). FDD is a method of processing transmission signals and reception signals by configuring the transmission frequency and reception frequency differently. If unnecessary frequency components are generated, inter modulation distortion (IMD) may be generated by mixing the transmission frequency with unnecessary frequency components, which may act as noise in the received signal and reduce reception sensitivity.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In a general aspect, a switch control circuit including a decoder configured to output a first command signal and a second command signal; a first driver configured to generate a first switching control signal which has one of a turn-on voltage and a turn-off voltage in response to the first command signal, and output the first switching control signal to a first switch connected between a first port and a second port; a delay cell configured to delay the second command signal; a logic gate configured to generate a third command signal based on a logical operation performed on the second command signal and the delayed second command signal; and a second driver configured to generate a second switching control signal which has one of a turn-on voltage and a turn-off voltage in response to the third command signal, and output the second switching control signal to a second switch connected between the first port and a ground or connected between the second port and the ground.

The logic gate may include an OR gate.

The first command signal and the second command signal may have a high level and a low level, and the decoder may be configured to output the high level when a turn-on command is given and output the low level when a turn-off command is given.

The first command signal may have the high level and the second command signal may have the low level, the first switch may be turned on at a first time in response to the turn-on voltage of the first switching control signal, and the second switch may be turned off at a second time after the first time in response to the turn-off voltage of the second switching control signal.

The second switch may be turned on in a period between the first time and the second time.

In a general aspect, a radio frequency (RF) switch circuit includes a first switch connected between a first port and a second port; a second switch connected between the first port and a ground, or connected between the second port and the ground; and a switching control circuit configured to generate a first switching control signal that controls an on operation and an off operation of the first switch and a second switching control signal that controls an on operation and an off operation of the second switch, wherein the switching control circuit includes a first driver configured to generate the first switching control signal which has a turn-on voltage corresponding to a first level of the first command signal and a turn-off voltage corresponding to a second level of the first command signal; a delay circuit configured to delay a second command signal having a complementary relationship with the first command signal, and generate a third command signal based on a logical operation performed on the second command signal and the delayed second command signal; and a second driver configured to generate the second switching control signal which has a turn-on voltage corresponding to a first level of the third command signal and a turn-off voltage corresponding to a second level of the third command signal.

The logical operation may be an OR operation.

The first level may be a high level, and the second level may be a low level.

The delay circuit may include a delay cell and an OR gate.

The first command signal may have the high level and the second command signal may have the low level, the first switch may be turned on at a first time in response to the turn-on voltage of the first switching control signal, and the second switch may be turned off at a second time after the first time in response to the turn-off voltage of the second switching control signal.

In a general aspect, a switch control method of a switch control circuit that controls a first switch connected between a first port and a second port, and a second switch connected between the first port and a ground or connected between the second port and the ground, the switch control method including generating a first command signal and a second command signal which has a complementary relationship with the first command signal; generating a first switching control signal which has a turn-on voltage corresponding to a first level of the first command signal and a turn-off voltage corresponding to a second level of the first command signal; outputting the first switching control signal to the first switch; generating a third command signal based on a logical OR operation performed on the second command signal and a delayed second command signal that is delayed by a delay time; generating a second switching control signal having a turn-on voltage corresponding to a first level of the third command signal and a turn-off voltage corresponding to a second level of the third command signal; and outputting the second switching control signal to the second switch.

The first level may be a high level, and the second level may be a low level.

After the first switch is turned on, the second switch may be turned off at least after the delay time.

Other features and aspects will be apparent from the following detailed description, the drawings, and the claims.

### BRIEF DESCRIPTION OF DRAWINGS

FIG. 1 illustrates an example a front-end module (FEM) implemented in a wireless communication system, in accordance with one or more embodiments.

FIG. 2 illustrates an example RF switch circuit shown in FIG. 1.

FIG. 3 illustrates switching noise generated in the RF switch circuit shown in FIG. 2.

FIG. 4 illustrates an example switching control circuit, in accordance with one or more embodiments.

FIG. 5 illustrates an example delay circuit shown in FIG. 4.

FIG. 6 illustrates an input signal of the delay cell, an output signal of an OR gate, and an output signal of a third driver shown in FIG. 5.

FIG. 7 illustrates an example of the delay cell shown in FIG. 5.

FIG. 8 is a timing diagram of a first switching control signal and a third switching control signal, in accordance with one or more embodiments.

FIG. 9 illustrates the operating principle of the delay cell circuit shown in FIG. 7.

Throughout the drawings and the detailed description, unless otherwise described, the same reference numerals refer to the same elements. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences within and/or of operations described herein are merely examples, and are not limited to those set forth herein, but may be changed as will be apparent after an understanding of the disclosure of this application, except for sequences within and/or of operations necessarily occurring in a certain order. As another example, the sequences of and/or within operations may be performed in parallel, except for at least a portion of sequences of and/or within operations necessarily occurring in an order, e.g., a certain order. Also, descriptions of features that are known after an understanding of the disclosure of this application may be omitted for increased clarity and conciseness.

Although terms such as “first,” “second,” and “third”, or A, B, (a), (b), and the like may be used herein to describe various members, components, regions, layers, or sections, these members, components, regions, layers, or sections are not to be limited by these terms. Each of these terminologies is not used to define an essence, order, or sequence of corresponding members, components, regions, layers, or sections, for example, but used merely to distinguish the corresponding members, components, regions, layers, or sections from other members, components, regions, layers, or sections. Thus, a first member, component, region, layer, or section referred to in the examples described herein may also be referred to as a second member, component, region, layer, or section without departing from the teachings of the examples.

Throughout the specification, when a component or element is described as “on,” “connected to,” “coupled to,” or “joined to” another component, element, or layer, it may be directly (e.g., in contact with the other component, element, or layer) “on,” “connected to,” “coupled to,” or “joined to” the other component element, or layer, or there may reasonably be one or more other components elements, or layers intervening therebetween. When a component or element is described as “directly on”, “directly connected to,” “directly coupled to,” or “directly joined to” another component element, or layer, there can be no other components, elements, or layers intervening therebetween. Likewise, expressions, for example, “between” and “immediately between” and “adjacent to” and “immediately adjacent to” may also be construed as described in the foregoing.

The terminology used herein is for describing various examples only and is not to be used to limit the disclosure. The articles “a,” “an,” and “the” are intended to include the plural forms as well, unless the context clearly indicates otherwise. As non-limiting examples, terms “comprise” or “comprises,” “include” or “includes,” and “have” or “has” specify the presence of stated features, numbers, operations, members, elements, and/or combinations thereof, but do not preclude the presence or addition of one or more other features, numbers, operations, members, elements, and/or combinations thereof, or the alternate presence of an alternative stated features, numbers, operations, members, elements, and/or combinations thereof. Additionally, while one embodiment may set forth such terms “comprise” or “comprises,” “include” or “includes,” and “have” or “has” specify the presence of stated features, numbers, operations, members, elements, and/or combinations thereof, other embodiments may exist where one or more of the stated features, numbers, operations, members, elements, and/or combinations thereof are not present.

As used herein, the term “and/or” includes any one and any combination of any two or more of the associated listed items. The phrases “at least one of A, B, and C”, “at least one of A, B, or C”, and the like are intended to have disjunctive meanings, and these phrases “at least one of A, B, and C”, “at least one of A, B, or C”, and the like also include examples where there may be one or more of each of A, B, and/or C (e.g., any combination of one or more of each of A, B, and C), unless the corresponding description and embodiment necessitates such listings (e.g., “at least one of A, B, and C”) to be interpreted to have a conjunctive meaning.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application. The use of the term “may” herein with respect to an example or embodiment (e.g., as to what an example or embodiment may include or implement) means that at least one example or embodiment exists where such a feature is included or implemented, while all examples are not limited thereto. The use of the terms “example” or “embodiment” herein have a same meaning (e.g., the phrasing “in one example” has a same meaning as “in one embodiment”, and “one or more examples” has a same meaning as “in one or more embodiments”).

Throughout the specification, an RF signal includes Wi-Fi (IEEE 802.11 family, etc.), WiMAX (IEEE 802.16 family, etc.), IEEE 802.20, long term evolution (LTE), Evolution-Data Optimized (Ev-DO), high-speed packet access plus (HSPA+), high-speed downlink packet access plus (HSDPA+), high-speed uplink packet access plus (HSUPA+), Enhanced Data GSM Evolution (EDGE), Global System for Mobile communication (GSM), Global Positioning System (GPS), General Packet Radio Service (GPRS), Code Division Multiple Access (CDMA), Time Division Multiple Access (TDMA), digital enhanced cordless communication (DECT), Bluetooth, third generation (3G), fourth generation (4G), fifth generation (5G), and any other wireless and wired protocols designated thereafter, but is not limited thereto.

One or more examples may provide a switch control circuit, a switch control method thereof, and a radio frequency switch circuit that reduces unnecessary frequency components.

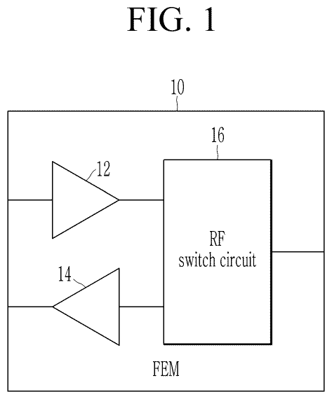

FIG. 1 illustrates an example of front-end module (FEM) that is implemented in a wireless communication system.

Referring to FIG. 1, the FEM 10 may include a power amplifier (PA) 12, a low noise amplifier (LNA) 14, and s radio frequency (RF) switch circuit 16.

The RF switch circuit 16 may select connection with either PA 12 or LNA 14.

The FEM 10 may be operated in a frequency division duplex (FDD) mode or method or a time division duplex (TDD) mode or method.

The FDD method enables signal transmission and signal reception at the same time by setting the transmission frequency band and reception frequency band differently. However, when intermodulation occurs due to mixing of the transmission frequency and unnecessary frequency components, the intermodulation component may cause distortion of the reception signal that is, intermodulation distortion (IMD), and thus the reception sensitivity may deteriorate. In an example, unnecessary frequency components may include the switching noise of switching elements in an RF switching circuit.

For example, assuming that the transmission frequency band is 1850 MHz to 1915 MHz, the reception frequency band is 1930 MHz to 1995 MHz, and the switching noise frequency is 15 MHz, IMD is expressed as the sum and difference of the transmission frequency and switching noise frequency. In this example, the sum of the transmission frequency of 1915 MHz and the switching noise frequency of 15 MHz is 1930 MHZ, and the difference between the transmission frequency of 1915 MHz and the switching noise frequency of 15 MHz is 1900 MHZ, and IMDs of 1900 MHz and 1930 MHz may be generated by the sum and difference of the transmission frequency of 1915 MHz and the switching noise frequency of 15 MHz. However, since 1930 MHz corresponds to the reception frequency, the IMD of 1930 MHz appears as the reception frequency. Therefore, distortion of the reception signal may occur due to the IMD of 1930 MHz.

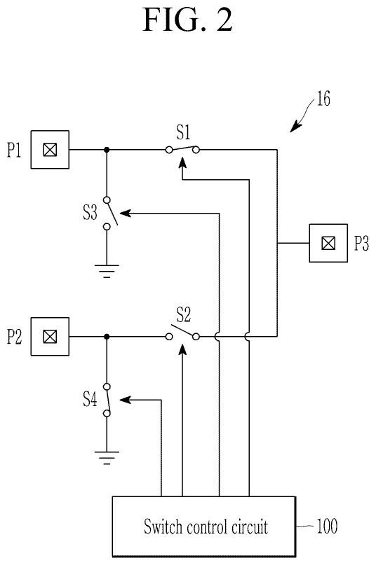

FIG. 2 illustrates an example RF switch circuit 16 illustrated in FIG. 1.

Referring to FIG. 2, the example RF switch circuit 16 may include a first port P1, a second port P2, a third port P3, a first switch S1, a second switch S2, a third switch S3, and a fourth switch S4. The RF switch circuit 16 may further include a switch control circuit 100.

The first switch S1, the second switch S2, the third switch S3, and the fourth switch S4 may be implemented with various transistors such as, but not limited to, a heterojunction bipolar transistor (HBT), a bipolar junction transistor (BJT), and an insulated gate bipolar transistor (IGBT). The first switch S1, the second switch S2, the third switch S3, and the fourth switch S4 may have a first terminal, a second terminal, and a control terminal, respectively. The ‘control terminal’ may be, for example, a gate of a transistor, or a base of a transistor. The first terminal and the second terminal may be a collector or an emitter of the transistor.

In an example, the first port P1 may be a transmission port, the second port P2 may be a reception port, and the third port P3 may be an output port or an antenna port for connection to an antenna. The path between the third port P3 and the first port P1 may be a transmission path. The path between the third port P3 and the second port P2 may be a reception path.

The first switch S1 may be connected between the first port P1 and the third port P3. The third switch S3 may be connected between the first port P1 and ground. The first switch S1 and the third switch S3 may operate complementary. When the first switch S1 is turned on, the third switch S3 may be turned off, and when the first switch S1 is turned off, the third switch S3 may be turned on.

The second switch S2 may be connected between the second port P2 and the third port P3. The fourth switch S4 may be connected between the second port P2 and ground. The second switch S2 and the fourth switch S4 may operate complementary. When the second switch S2 is turned on, the fourth switch S4 may be turned off, and when the second switch S2 is turned off, the fourth switch S4 may be turned on.

The switch control circuit 100 may control on and off operations of the first switch S1, the second switch S2, the third switch S3, and the fourth switch S4 according to an operation mode of the RF switch circuit 16.

Typically, the chip sizes of the first switch S1 and the second switch S2 located on the signal path may be set larger than the chip sizes of the third switch S3 and the fourth switch S4 to terminate the signal to ground. Depending on the size of this chip, the time taken for the first switch S1 or the second switch S2 to turn on or off may be longer than the time taken for the third switch S3 or the fourth switch S4 to turn on or off. Additionally, the first switch S1, the second switch S2, the third switch S3, and the fourth switch S4 may be turned on when the voltages of the control terminals are charged above the threshold voltage for turn on, and may be turned off when the voltages of the control terminals are discharged. At this time, the time it takes to turn on by charging the voltages of the control terminal to the threshold voltage may be longer that the time it takes to turn off by discharging the voltages of the control terminal. Therefore, the time delay when the first switch S1, the second switch S2, the third switch S3, and the fourth switch S4 are turned on may be longer than the time delay when the first switch S1, the second switch S2, the third switch S3, and the fourth switch S4 are turned off. The switching noise may be generated due to differences in switching times of these switches S1, S2, S3, and S4.

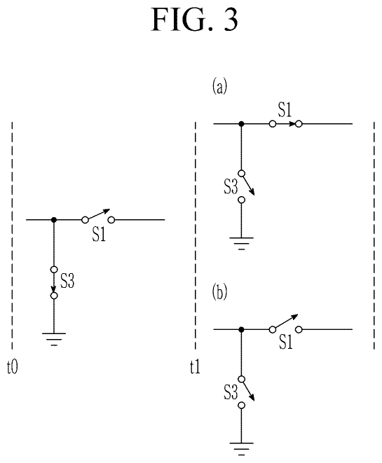

FIG. 3 illustrates switching noise generated in the RF switch circuit shown in FIG. 2. In FIG. 3, the first switch S1 and the third switch S3 are shown for convenience.

Referring to FIG. 3, the first switch S1 and the third switch S3 each perform an on-off operation in response to a switching control signal received from the switch control circuit 100.

At time to, the first switch S1 may be in an off state and the third switch S3 may be in an on state. Thereafter, at time t1, assume that the first switch S1 may receive a switching control signal having a turn-on voltage from the switch control circuit 100, and the third switch S3 may receive a switching control signal having a turn-off voltage from the switch control circuit 100.

Then, as shown in (a), if the first switch S1 is turned on and the third switch S3 is turned off at the same time ideally, the switching noise may not occur in a transient period where the switching states of the first switch S1 and the third switch S3 is changed. However, due to the difference between the time it takes for the first switch S1 to turn on and the time it takes for the third switch S3 to turn off, as shown in (b), before the first switch S1 is completely switched from the off state to the on state, the third switch S3 may be switched from the on state to the off state, and thus in the transition period of the first switch S1 and the third switch S3, both the first switch S1 and the third switch S3 may be turned off, and the switching noise may be generated.

As described above, the switching noise generated in this manner operates as an unnecessary frequency component and may cause signal distortion. For example, the transmission frequency and unnecessary frequency components may be mixed, this may cause distortion of the reception signal. In another example, the reception frequency and unnecessary frequency components may be mixed, this may cause distortion of the transmission signal.

The switch control circuit 100, in accordance with one or more embodiments, may provide a method of improving switching noise that may occur in the transition period of switches.

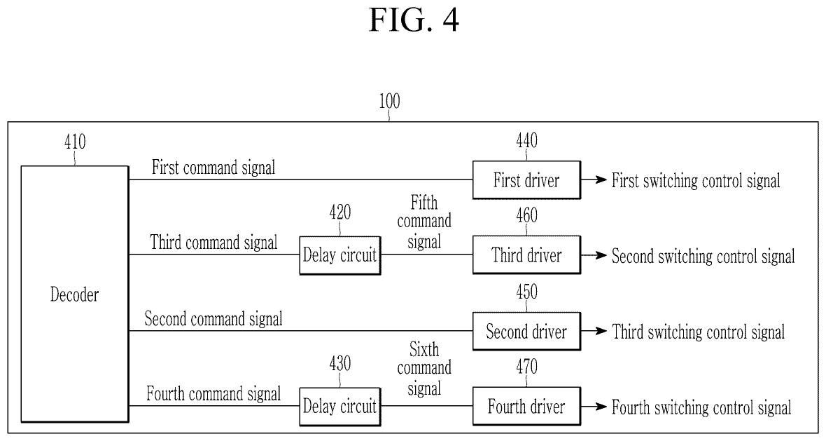

FIG. 4 illustrates an example switch control circuit, in accordance with one or more embodiments.

Referring to FIG. 4, the switch control circuit 100 may include a decoder 410, delay circuits 420 and 430, and a plurality of drivers 440, 450, 460, and 470. For convenience, the plurality of drivers 440, 450, 460, and 470 are respectively referred to as first driver 440, second driver 450, third driver 460, and fourth driver 470.

The decoder 410 may generate a first command signal, a second command signal, a third command signal, and a fourth command signal which respectively indicate switching commands for each of the first switch S1, the second switch S2, the third switch S3, and the fourth switch S4 according to the mode signal.

The decoder 410 may output a first command signal to the first driver 440 and a second command signal to the second driver 450. In an example, the decoder 410 may output a third command signal to the delay cell circuit 420 and a fourth command signal to the delay cell circuit 430. That is, the third command signal and the fourth command signal may be respectively output to the third driver 460 and the fourth driver 470 through the delay cell circuit 420 and the delay cell circuit 430.

The delay circuit 420 may delay the third command signal by a set delay time and generate a fifth command signal through a predetermined logical operation on the third command signal and the delayed third command signal, and output the fifth command signal to the third driver 460.

The delay circuit 430 may delay the fourth command signal by a set delay time and generate a sixth command signal through a predetermined logical operation on the fourth command signal and the delayed fourth command signal, and output the sixth command signal to the fourth driver 470.

The first driver 440 may provide a first switching control signal having a turn-on voltage or a turn-off voltage to the first switch S1 in response to the first command signal. For example, if the first command signal is at a high level, a first switching control signal having a turn-on voltage may be provided, and if the first command signal is at a low level, a first switching control signal having a turn-off voltage may be provided.

The second driver 450 may provide a second switching control signal having a turn-on voltage or a turn-off voltage to the second switch S2 in response to the second command signal. For example, if the second command signal is at a high level, a second switching control signal having a turn-on voltage may be provided, and if the second command signal is at a low level, a second switching control signal having a turn-off voltage may be provided.

The third driver 460 may provide a third switching control signal having a turn-on voltage or turn-off voltage to the third switch S3 in response to the fifth command signal output from the delay circuit 420. For example, if the fifth command signal is at a high level, a third switching control signal having a turn-on voltage may be provided, and if the fifth command signal is at a low level, a third switching control signal having a turn-off voltage may be provided.

The fourth driver 470 may provide a fourth switching control signal having a turn-on voltage or turn-off voltage to the fourth switch S4 in response to the sixth command signal output from the delay circuit 430. For example, if the sixth command signal is at a high level, a fourth switching control signal having a turn-on voltage may be provided, and if the sixth command signal is at a low level, a fourth switching control signal having a turn-off voltage may be provided.

In an example, the turn-on voltage may be a positive voltage, and the turn-off voltage may be a negative voltage or a ground voltage.

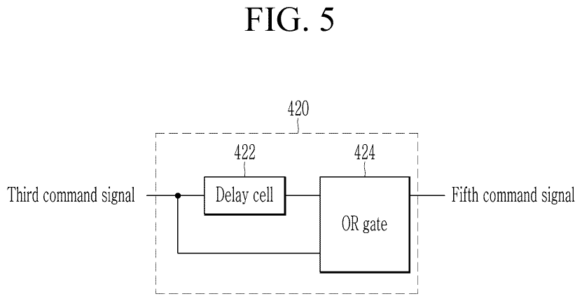

FIG. 5 illustrates an example of a delay circuit shown in FIG. 4.

Although the delay circuit 420 is shown in FIG. 5, the delay circuit 430 may also be configured in the same manner as the delay circuit 420.

Referring to FIG. 5, the delay circuit 420 may include a delay cell 422 and an OR gate 424, which is an OR element.

The third command signal may be input to the delay cell 422.

The delay cell 422 may delay the third command signal by the delay time and then output the delayed third command to the OR gate 424.

The third command signal and the third command signal delayed from the delay cell 422 may each be input to two input terminals of the OR gate 424.

The OR gate 424 may generate the fifth command signal by performing an OR operation on signals input from the two input terminals, and output the fifth command signal. The OR gate 424 may output the fifth command signal having a high level when one or both signals of the two input terminals are high level and a low level when both signals of the two input terminals are low level.

That is, the fifth command signal output from the OR gate 424 may be a signal in which the time for maintaining the high level of the third command signal is longer by the delay time.

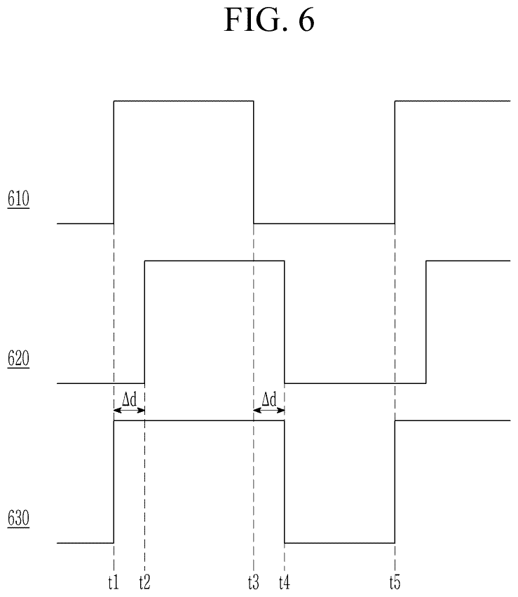

FIG. 6 illustrates an input signal of the delay cell, an output signal of an OR gate, and an output signal of a third driver shown in FIG. 5.

In FIG. 6, 610 is an input signal of a delay cell and may be the third command signal. A high level of the third command signal may mean turn-on of the third switch S3, and a low level of the third command signal may mean turn-off of the third switch S3. 620 is the output signal of the delay cell 422, and 630 is the output signal of the OR gate 424, and may be the fifth command signal.

Referring to FIG. 6, at time t1, when the third command signal 610 having the high level is output, and at time t2, which is delayed by the delay time Δd of the delay cell 422 from time t1, the output signal 620 of the delay cell 422 may become a high level. At time t3, when the third command signal 610 having the low level is output, and at time t4, which is delayed by the delay time Δd of the delay cell 422 from time t3, the output signal 620 of the delay cell 422 may become a low level. Accordingly, the output signal 630 of the OR gate 424 may have a high level from time t1 to time t4, and may have a low level from time t4 until time t5 which the third command signal 610 becomes high level.

The first command signal and the third command signal have a complementary relationship. When the first command signal changes to high level and the third command signal changes to low level, the delay circuit 420 may maintain the third command signal at the high level for the delay time Δd of the delay cell 422 and then change the third command to the low level.

Accordingly, the third switch S3 may be turned off after the first switch S1 is completely turned on, so there may be no period in which the first switch S1 and the third switch S3 are turned off at the same time.

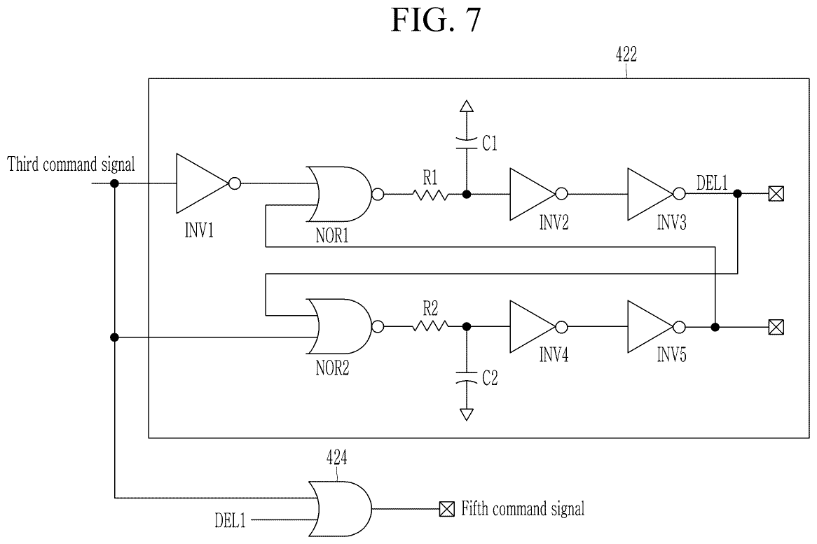

FIG. 7 illustrates an example of the delay cell shown in FIG. 5.

Referring to FIG. 7, the delay cell 422 may include a plurality of inverters INV1, INV2, INV3, INV4, and INV5 and at least one NOR gate NOR1, and NOR2. Additionally, the delay cell 422 may further include resistors R1 and R2, and capacitors C1 and C2.

The inverter INV1 may invert the third command signal and output the inverted third command.

The NOR gate NOR1 may receive the output signal of the inverter INV1 and the output signal of the inverter INV5, perform a NOR operation on the output signal of the inverter INV1 and the output signal of the inverter INV5, and output them. The NOR gate NOR1 may output 1 only when the output signal of the inverter INV1 and the output signal of the inverter INV5 are both 0, otherwise, the NOR gate NOR1 may output 0.

The inverter INV2 may invert the output signal of the NOR gate NOR1 and output the inverted signal.

The inverter INV3 may invert the output signal of the inverter INV2 and output the inverted signal.

The NOR gate NOR2 may receive the third command signal and the output signal of the inverter INV3, perform a NOR operation on the third command signal and the output signal of the inverter INV3, and then output them. The NOR gate NOR2 may output 1 only when the third command signal and the output signal of the inverter INV3 are both 0, otherwise, the NOR gate NOR2 may output 0.

The inverter INV4 may invert the output signal of the NOR gate NOR2 and output the inverted signal.

The inverter INV5 may invert the output signal of the inverter INV4 and output the inverted signal.

The resistor R1 may be connected between the NOR gate NOR1 and the inverter INV2, and the capacitor C1 may be connected between an input of the inverter INV2 and ground.

The resistor R2 may be connected between the NOR gate NOR2 and the inverter INV4, and the capacitor C2 may be connected between an input of the inverter INV4 and ground.

The output signal DEL1 of the inverter INV3 may be input to the input terminal of the OR gate 424. That is, the output signal of the OR gate 424 is the output signal DEL1 of the inverter INV3, and the output signal DEL1 of the inverter INV3 may correspond to 620 in FIG. 6.

The circuit shown in FIG. 7 is an example of the delay cell 422, and may be implemented as a different circuit. In an example, a NAND gate may be used instead of the NOR gate shown in FIG. 7, and various non-overlapping delay cell circuits may be used as the delay cell 422.

Additionally, depending on the delay cell 422 used, other logic elements may be used instead of the OR gate 424.

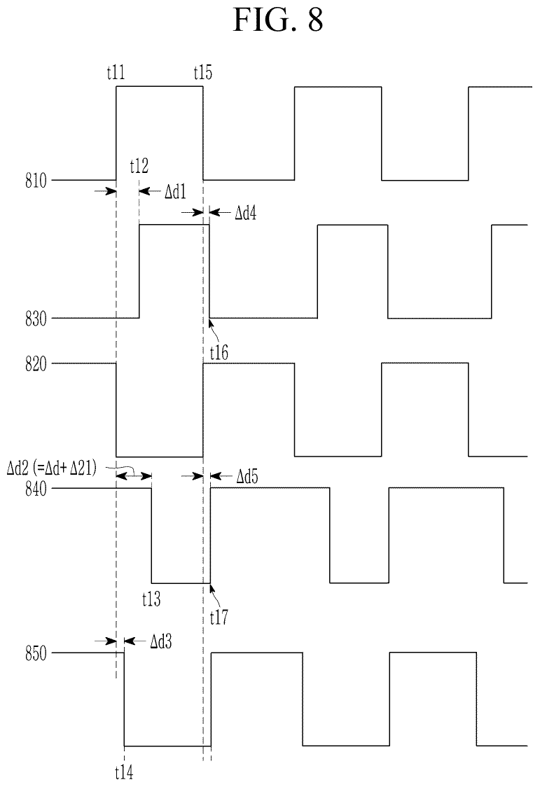

FIG. 8 is a timing diagram of a first switching control signal and a third switching control signal, in accordance with one or more embodiments.

In FIG. 8, 810 represents the first command signal and 820 represents the third command signal. 830 represents a control terminal voltage of the first switch S1 corresponding to the first switching control signal, and 840 represents a control terminal voltage of the third switch S3 corresponding to the third switching control signal. 850 represents a control terminal voltage of the third switch S3 corresponding to the third switching control signal assuming that there is no delay circuit 420.

Referring to FIG. 8, at time t11, the first command signal may be changed to high level and the third command signal may be changed to low level.

The first switching control signal having a turn-on voltage corresponding to the high level of the first command signal may be input to the control terminal of the first switch S1.

The control terminal of the first switch S1 may have a turn-on voltage at time t12 after a predetermined delay Δd1 from time t11, and accordingly, the first switch S1 may be turned on at time t12. At this time, the delay Δd1 represents the on-switching delay time of the first switch S1 corresponding to the turn-on voltage, and the on-switching delay time of the first switch S1 may be longer than the on-switch delay time of the third switch S3 by the chip size of the first switch S1 and chip size of the third switch S3.

Unlike the embodiment, if there is no delay circuit 420, the third switching control signal having a turn-off voltage without delay time Δd in response to the low level of the third command signal may be input to the control terminal of the third switch S3. Then, the control terminal of the third switch S3 may have a turn-off voltage at time t14 after a predetermined delay Δd3 from time t11, and accordingly, the third switch S3 may be turned off at time t14. At this time, the delay Δd3 may represent the off-switching delay time of the third switch S3.

As such, if there is no delay circuit 420, a situation occurs in which both the first switch S1 and the third switch S3 are turned off in the period between time t14 and time t12, and switching noise may be generated at this time.

In an example, the third switching control signal having a turn-off voltage at a time when the delay time Δd of the delay cell 422 has elapsed from the time t11 in response to the low level of the third command signal, may be input to the control terminal of the third switch S3.

Then, the control terminal of the third switch S3 may have a turn-off voltage at time t13 after a predetermined delay Δd2 from time t11, and accordingly, the third switch S3 may be turned off at time t13. At this time, the delay Δd2 may be the sum of the delay time Δd and the delay time Δd21, and the delay time Δd21 may represent the off-switching delay time of the third switch S3.

Accordingly, the third switching control signal has a turn-off voltage after being delayed by the delay time Δd in response to the low level of the third command signal, so after the first switch S1 may be completely turned on, the third switch S3 may be turned off. Accordingly, there may be no situation in which both the first switch S1 and the third switch S3 are turned off in the transition period of the first switch S1 and the third switch S3.

Meanwhile, a situation may occur in which the first switch S1 and the third switch S3 are turned on at the same time in the transition period of the first switch S1 and the third switch S3. In this example, since the RF signal may be split to ground through the switch S3, the RF signal may be transmitted normally by setting the turn-on period of the first switch S1 to be long.

At time t14, the first command signal may be changed to low level and the third command signal may be changed to high level.

The first switching control signal having a turn-off voltage corresponding to the low level of the first command signal may be input to the control terminal of the first switch S1.

The control terminal of the first switch S1 may have a turn-off voltage at time t16 after a predetermined delay Δd4 from time t15, and accordingly, the first switch S1 may be turned off at time t16. In an example, the delay Δd4 represents the off-switching delay time of the first switch S1 corresponding to the turn-off voltage, and the off-switching delay time of the first switch S1 may be smaller than the on-switching delay time of the first switch S1.

The third switching control signal having a turn-on voltage corresponding to the high level of the third command signal may be input to the control terminal of the third switch S3.

The control terminal of the third switch S3 may have a turn-on voltage at time t17 after a predetermined delay Δd5 from time t14, and accordingly, the third switch S3 may be turned on at time t17. In an example, the delay Δd5 represents the on-switching delay time of the third switch S3 corresponding to the turn-on voltage, and the on-switching delay time of the third switch S3 may be similar to the off-switching delay time of the first switch S1.

Accordingly, when the first command signal changes to low level and the third command signal changes to high level, the first switch S1 may be turned off and the third switch S3 may be turned on.

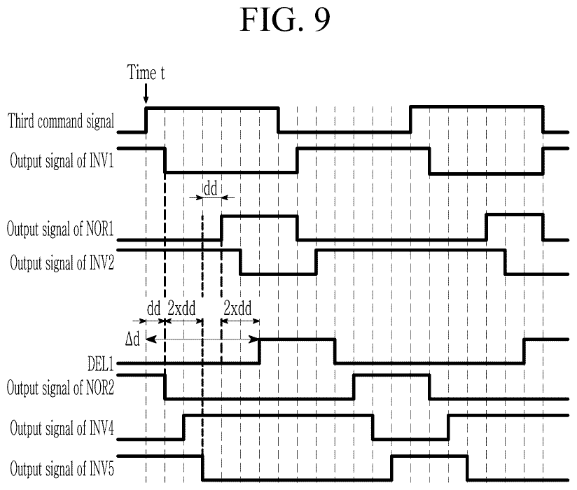

FIG. 9 illustrates the operating principle of the delay cell circuit shown in FIG. 7.

Referring to FIG. 9, the third command signal may be input to the inverter INV1 and the NOR gate NOR2. For convenience of explanation, it is assumed that the internal processing delay time of the inverters INV1, INV2, INV3, INV4, and INV5 and the NOR gates NOR1, and NOR2 of the delay cell 422 is dd. Of course, the internal processing delay times of the inverters INV1, INV2, INV3, INV4, and INV5 and NOR gates NOR1, and NOR2 may be different.

According to the embodiment, the output signal of the delay cell 422 is the output signal DEL1 of the inverter INV3, and the output signal DEL1 of the inverter INV3 has the same phase as the output signal of the NOR gate NOR1, and it may be a signal delayed by the internal processing delay time (i.e., 2×dd) of the inverters INV2, and INV3.

The NOR gate NOR1 may output a high level when both the output signal of the inverter INV1 and the output signal of the inverter INV5 are low level. At this time, the output signal of the inverter INV1 is the inversion signal of the third command signal, when the third command signal becomes high level at time t, the output signal of the inverter INV1 becomes low level at time (t+dd), so the NOR gate NOR1 may output a high-level signal after the internal processing delay time dd of the NOR gate NOR1 when the output signal of the inverter INV5 becomes low level.

The output signal of the inverter INV5 may have the same phase as the output signal of the NOR gate NOR2, and it may be a signal delayed by the internal processing delay time (i.e., 2×dd) of the inverters INV4, and INV5.

The NOR gate NOR2 may output a low level when at least one of the third command signal and the output signal DEL1 of the inverter INV3 is high level, so when the third command signal becomes high level at the time t, the output signal of the NOR gate NOR2 may be at low level at time (t+dd).

Ultimately, the delay cell 422 may output a signal having a high level after being delayed by a delay time Δd=6×dd from the time t in response to the high level of the third command signal. In addition, the delay cell 422 may output a signal having a low level after being delayed by a predetermined delay time in response to the low level of the third command signal.

According to at least one of the embodiments, in the RF switch circuit, by turning off a switch that connects a signal to ground after a switch in a signal path is turned on, a period in which both switches are turned off during a transitional period in which the switching states of the switches are changed may be eliminated. Accordingly, switching noise may be reduced in the transition period and reception sensitivity may be improved.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents.

Therefore, in addition to the above and all drawing disclosures, the scope of the disclosure is also inclusive of the claims and their equivalents, i.e., all variations within the scope of the claims and their equivalents are to be construed as being included in the disclosure.

What is claimed is:

1. A switch control circuit, comprising:
a decoder configured to output a first command signal and a second command signal;
a first driver configured to generate a first switching control signal which has one of a turn-on voltage and a turn-off voltage in response to the first command signal, and output the first switching control signal to a first switch connected between a first port and a second port;
a delay cell configured to delay the second command signal;
a logic gate configured to generate a third command signal based on a logical operation performed on the second command signal and the delayed second command signal; and
a second driver configured to generate a second switching control signal which has one of a turn-on voltage and a turn-off voltage in response to the third command signal, and output the second switching control signal to a second switch connected between the first port and a ground or connected between the second port and the ground.

2. The switch control circuit of claim 1, wherein the logic gate comprises an OR gate.

3. The switch control circuit of claim 2, wherein:
the first command signal and the second command signal have a high level and a low level, and
the decoder is configured to output the high level when a turn-on command is given and output the low level when a turn-off command is given.

4. The switch control circuit of claim 2, wherein:
when the first command signal has the high level and the second command signal has the low level, the first switch is turned on at a first time in response to the turn-on voltage of the first switching control signal, and the second switch is turned off at a second time after the first time in response to the turn-off voltage of the second switching control signal.

5. The switch control circuit of claim 4, wherein the second switch is turned on in a period between the first time and the second time.

6. A radio frequency (RF) switch circuit, comprising:
a first switch connected between a first port and a second port;
a second switch connected between the first port and a ground, or connected between the second port and the ground; and
a switching control circuit configured to generate a first switching control signal that controls an on operation and an off operation of the first switch and a second switching control signal that controls an on operation and an off operation of the second switch,
wherein the switching control circuit comprises:
a first driver configured to generate the first switching control signal which has a turn-on voltage corresponding to a first level of the first command signal and a turn-off voltage corresponding to a second level of the first command signal;
a delay circuit configured to delay a second command signal having a complementary relationship with the first command signal, and generate a third command signal based on a logical operation performed on the second command signal and the delayed second command signal; and
a second driver configured to generate the second switching control signal which has a turn-on voltage corresponding to a first level of the third command signal and a turn-off voltage corresponding to a second level of the third command signal.

7. The RF switch circuit of claim 6, wherein the logical operation is an OR operation.

8. The RF switch circuit of claim 7, wherein the first level is a high level, and the second level is a low level.

9. The RF switch circuit of claim 6, wherein the delay circuit comprises a delay cell and an OR gate.

10. The RF switch circuit of claim 7, wherein:
when the first command signal has the high level and the second command signal has the low level, the first switch is turned on at a first time in response to the turn-on voltage of the first switching control signal, and the second switch is turned off at a second time after the first time in response to the turn-off voltage of the second switching control signal.

11. A switch control method of a switch control circuit that controls a first switch connected between a first port and a second port, and a second switch connected between the first port and a ground or connected between the second port and the ground, the switch control method comprising:
generating a first command signal and a second command signal which has a complementary relationship with the first command signal;
generating a first switching control signal which has a turn-on voltage corresponding to a first level of the first command signal and a turn-off voltage corresponding to a second level of the first command signal;
outputting the first switching control signal to the first switch;
generating a third command signal based on a logical OR operation performed on the second command signal and a delayed second command signal that is delayed by a delay time;
generating a second switching control signal having a turn-on voltage corresponding to a first level of the third command signal and a turn-off voltage corresponding to a second level of the third command signal; and
outputting the second switching control signal to the second switch.

12. The switch control method of claim 11, wherein the first level is a high level, and the second level is a low level.

13. The switch control method of claim 11, wherein after the first switch is turned on, the second switch is turned off at least after the delay time.
